(19) United States
(12) Patent Application Publication
(10) Pub. No.: US 2007/0095653 A1
(43) Pub. Date: May 3, 2007

(54) METHOD FOR MANUFACTURING CONDUCTIVE COMPLEX OXIDE LAYER, AND METHOD FOR MANUFACTURING LAMINATED BODY HAVING FERROELECTRIC LAYER

(75) Inventors: Koji OHASHI, Chino (JP); Setsuya IWASHITA, Nirasaki (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 11/551,440

(22) Filed: Oct. 20, 2006

(30) Foreign Application Priority Data
Oct. 31, 2005 (JP) 2005-316968

(51) Int. Cl. C23C 14/00

(52) U.S. Cl. 204/192.15

(57) ABSTRACT

A method for manufacturing a conductive complex oxide layer includes the steps of: forming, above a base substrate, a first layer of conductive complex oxide expressed by a general formula of ABO₃ by first sputtering with first oxygen concentration; and forming, above the first layer of conductive complex oxide, a second layer of conductive complex oxide expressed by a general formula of ABO₃ by second sputtering at least with second oxygen concentration lower than the first oxygen concentration.

The entire disclosure of Japanese Patent Application No. 2005-316968 filed Oct. 31, 2005 is expressly incorporated by reference herein.

### BACKGROUND

1. Technical Field

The present invention relates to a method for manufacturing a conductive complex oxide layer, and a method for manufacturing a laminated body having a ferroelectric layer and a method for manufacturing a device to which the aforementioned method for manufacturing a conductive complex oxide is applied.

2. Related Art

As one of the methods for forming a film of conductive complex oxide expressed by a general formula of ABO₃, a sputter method is known. The sputter method normally uses an atmosphere in which inert gas as discharge gas and oxygen as oxidizing gas exist together.

### SUMMARY

In accordance with an advantage of some aspects of the present invention, it is possible to provide a method for manufacturing a conductive complex oxide layer by which a conductive complex oxide layer with excellent crystallinity can be obtained.

In accordance with another advantage of some aspects of the invention, it is possible to provide a method for manufacturing a laminated body having a ferroelectrlc layer to which the method for manufacturing a conductive complex oxide layer in accordance with the embodiment of the invention is applied.

In accordance with still another advantage of some aspects of the invention, it is possible to provide a method for manufacturing a device to which the method for manufacturing a laminated body in accordance with the embodiment of the invention is applied.

A method for manufacturing a conductive complex oxide layer in accordance with an embodiment of the invention includes the steps of: forming, above a base substrate, a first layer of conductive complex oxide expressed by a general formula of ABO₃ by first sputtering with first oxygen concentration, and forming, above the first layer of conductive complex oxide, a second layer of conductive complex oxide expressed by a general formula of ABO₃ by second sputtering at least with second oxygen concentration lower than the first oxygen concentration.

In the method for manufacturing a conductive complex oxide layer in accordance with the present embodiment of the invention, when a conductive complex oxide layer is formed by sputtering, a first sputtering step that is conduced with first oxygen concentration and a second sputtering step that is conducted at least with second oxygen concentration lower than the first oxygen concentration are conducted, whereby the conductive complex oxide layer with excellent crystallinity and surface morphology can be formed.

It is noted that, in the invention, the case where a specific layer B (hereafter referred to as a “layer B”) is provided above a specific layer A (hereafter referred to as a “layer A”) includes a case where the layer B is directly provided on the layer A, and a case where the layer B is provided over the layer A through another layer.

In the method for manufacturing a conductive complex oxide layer in accordance with an aspect of the present embodiment of the invention, the first sputtering may be conducted where inert gas and oxygen coexist.

In the method for manufacturing a conductive complex oxide layer in accordance with another aspect of the present embodiment of the invention, the first layer of conductive complex oxide and the second layer of conductive complex oxide may be composed of the same compound.

In the method for manufacturing a conductive complex oxide layer in accordance with another aspect of the present embodiment of the invention, the second sputtering may be conducted in an atmosphere that does not include oxygen.

In the method for manufacturing a conductive complex oxide layer in accordance with another aspect of the present embodiment of the invention, heat treatment may be conducted after the second layer of conductive complex oxide has been formed.

In the method for manufacturing a conductive complex oxide layer in accordance with the present embodiment of the invention, the element A may be at least one element selected from La, Ca, Sr, Mn, Ba and Re, and the element B may be at least one element selected from Ti, V, Sr, Cr, Fe, Co, Ni, Cu, Ru, Ir, Pb and Nd.

In the method for manufacturing a conductive complex oxide layer in accordance with the present embodiment of the invention, the element A may be La, and the element B may be Ni.

In the method for manufacturing a conductive complex oxide layer in accordance with the present embodiment of the invention, the sputtering may be RF sputtering.

A method for manufacturing a laminated body including a ferroelectric layer in accordance with another embodiment of the invention includes the steps of: forming, above a base substrate, a first layer of conductive complex oxide expressed by a general formula of ABO₃ by first sputtering with first oxygen concentration, forming above the first layer of conductive complex oxide, a second layer of conductive complex oxide expressed by a general formula of ABO₃ by second sputtering at least with second oxygen concentration lower than the first oxygen concentration, and forming a ferroelectric layer above the second layer of conductive complex oxide.

According to the method for manufacturing a laminated body in accordance with the present embodiment of the invention, a layer of conductive complex oxide with excellent characteristics can be obtained, such that the laminated body with excellent hysteresis characteristics and piezoelectric characteristics can be obtained.

The method for manufacturing a laminated body having a ferroelectric layer in accordance with an aspect of the present embodiment of the invention may include the step of forming a layer of conductive complex oxide expressed by a general formula of ABO₃ by sputtering above the ferroelectric layer.

In the method for manufacturing a laminated body having a ferroelectric layer in accordance with another aspect of the present embodiment of the invention, the step of forming the layer of conductive complex oxide may include the step of forming a third layer of conductive complex oxide expressed by a general formula of ABO₃ by third sputtering conducted with the first oxygen concentration, and the step of forming, above the third layer of conductive complex oxide, a fourth layer of conductive complex oxide expressed by a general formula of ABO₃ by fourth sputtering conducted at least with the second oxygen concentration having a lower oxygen concentration than the first oxygen concentration.

A method for manufacturing a laminated body having a ferroelectric layer in accordance with another embodiment of the invention includes the steps of: forming a ferroelectric layer above a base substrate, forming, above the ferroelectric layer, a first layer of conductive complex oxide expressed by a general formula of ABO₃ by first sputtering with first oxygen concentration, and forming, above the first layer of conductive complex oxide, a second layer of conductive complex oxide expressed by a general formula of ABO₃ by second sputtering at least with second oxygen concentration lower than the first oxygen concentration.

According to the method for manufacturing a laminated body in accordance with the present embodiment of the invention, a layer of conductive complex oxide with excellent characteristics can be obtained, and therefore a laminated body with excellent piezoelectric characteristics can be obtained.

A method for manufacturing a device in accordance with another embodiment of the invention includes the method for manufacturing a laminated body in accordance with the embodiment of the invention described above.

Devices to which the manufacturing method in accordance with the embodiment of the invention is applicable will be described below.

### BRIEF DESCRIPTION OF THE DRAWINGS

FIG. 1 schematically shows a step of a method for manufacturing a first laminated body in accordance with an embodiment of the invention.

FIG. 2 schematically shows a step of the method for manufacturing the first laminated body in accordance with the embodiment of the invention.

FIG. 3 schematically shows a step of the method for manufacturing the first laminated body in accordance with the embodiment of the invention.

FIG. 4 schematically shows a step of the method for manufacturing the first laminated body in accordance with the embodiment of the invention.

FIG. 5 schematically shows a step of the method for manufacturing the first laminated body in accordance with the embodiment of the invention.

FIG. 6 schematically shows a step of a method for manufacturing a second laminated body in accordance with an embodiment of the invention.

FIG. 7 shows results of X-ray analysis conducted on laminated bodies of an embodiment example and a comparison example.

FIG. 8 shows a surface morphology of the laminated body of the embodiment example.

FIG. 9 shows a surface morphology of the laminated body of the comparison example.

FIG. 10 shows results of X-ray analysis conducted on the laminated body of the embodiment example.

FIG. 11 shows hysteresis characteristics of capacitors in accordance with an embodiment example and a comparison example.

FIGS. 12A and 12B schematically show a plan view and a cross-sectional view of a semiconductor device in accordance with an embodiment of the invention, respectively.

FIG. 13 schematically shows a cross-sectional view of a 1T1C type ferroelectric memory in accordance with an embodiment of the invention.

FIG. 14 shows an equivalent circuit of the ferroelectric memory shown in FIG. 13.

FIG. 15 shows a cross-sectional view schematically showing a piezoelectric element in accordance with an application example of an embodiment of the invention.

FIG. 16 shows a schematic structural view of an ink jet recording head in accordance with an application example of an embodiment of the invention.

FIG. 17 shows an exploded perspective view of an ink jet recording head in accordance with an embodiment of the invention.

FIG. 18 shows a schematic structural view of an ink jet printer in accordance with an application example of an embodiment of the invention.

FIG. 19 is a cross-sectional view of a surface acoustic wave element in accordance with an application example of an embodiment of the invention.

FIG. 20 is a perspective view of a frequency filter in accordance with an application example of an embodiment of the invention.

FIG. 21 is a perspective view of an oscillator in accordance with an application example of an embodiment of the invention.

### DESCRIPTION OF EXEMPLARY EMBODIMENTS

Preferred embodiments of the invention are described below in detail with reference to the accompanying drawings.

1. Method for Manufacturing First Laminated Body having Ferroelectric Layer

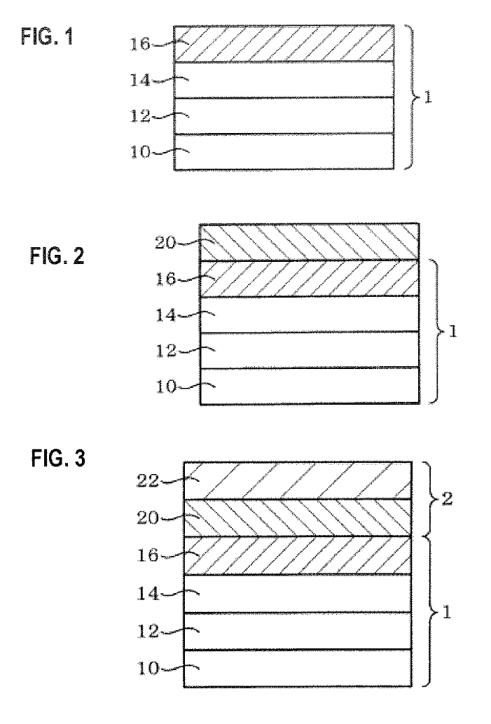

A method for manufacturing a first laminated body in accordance with an embodiment of the invention is described with reference to FIGS. 1 through 5. FIGS. 1 through 3 schematically show steps of a method for manufacturing a conductive complex oxide layer in accordance with an embodiment of the invention.

(1) First, as shown in FIG. 1, a base substrate 1 is prepared In the illustrated example, the base substrate 1 is formed by successively laminating a silicon oxide layer 12, a titanium oxide layer 14 and a platinum layer 16 on a silicon substrate 10. For example, the base substrate 1 may be formed as follows.

The silicon oxide layer 12 is formed on the silicon substrate 10. Then, the titanium oxide layer 14 is formed on the silicon oxide layer 12 by DC (direct current) sputtering or the like. The titanium oxide layer 14 can improve adhesion between the silicon oxide layer 12 and the platinum layer 16. The titanium oxide layer 14 may have a film thickness of, for example, 10-40 nm. A titanium layer may be used instead of the titanium oxide layer 14. Then, the platinum layer 16 is formed on the titanium oxide layer 14 by DC (direct current) sputtering or the like. The platinum layer 16 may have a film thickness of, for example, 50-200 nm. A layer of another platinum group metal may also be used instead of the platinum layer 16.

The type of the base substrate 1 can be selected depending on the usage of a layer of conductive complex oxide. An insulating substrate, a semiconductor substrate or the like can be used as the base substrate 1, and its structure is not particularly limited. As the insulating substrate, for example, a sapphire substrate, a plastic substrate, a glass substrate or the like can be used, As the semiconductor substrate, a silicon substrate, a germanium substrate, a TiO₂ substrate, a ZnO substrate, a NiOₓ substrate or the like can be used. Also, the base substrate 1 may be formed with a single substrate or a laminated body in which at least one layer is laminated on a substrate.

(2) As shown in FIG. 2, a first layer of conductive complex oxide 20 of perovskite type expressed by a general formula ABO₃ is formed on the base substrate 1.

In the general formula, the element A may be at least one element selected from La, Ca, Sr, Mn, Ba and Re, and the element B may be at least one element selected from Ti, V, Sr, Cr, Fe, Co, Ni, Cu, Ru, Ir, Pb and Nd. Also, as the layer of conductive complex oxide in accordance with an embodiment of the invention, LaCoO₃, SrCoO₃, La₁₋ₓ Srₓ CoO₃ [where x and y is a rational number of 0-1, and the same applies to the following chemical formulas], such as, La (Sr) CoO₃ [where a metal in the brackets ( ) means a substitution metal, and the same applies to the following chemical formulas], LaMnO₃, SrMnO₃, La₁₋ₓ Srₓ MnO₃, such as, La (Sr) MnO₃, LaNiO₃, SrNiO₃, La(Sr)NiO₃, CaCoO₃, La(Ca)CoO₃, LaFeO₃, SrFeO₃, La(Sr)FeO₃, La₁₋ₓ SrₓCo_{1-y} Fe_{y} O₃, such as, La(Sr)Co(Fe)O₃ or La₁₋ₓSrₓVO₃, La₁₋ₓCaₓFeO₃, LaBaO₃, LaMnO₃, LaCuO₃, LaTiO₃, BaCeO₃, BaTiO₃, BaSnO₃, BaPbO₃, BaPb₁₋ₓO₃, CaCrO₃, CaVO₃, CaRuO₃, SrIrO₃, SrFeO₃, SrVO₃, SrRuO₃, Sr(Pt)RuO₃, SrTiO₃, SrReO₃, SrCeO₃, SrCrO₃, BaReO₃, BaPb₁₋ₓBiₓO₃, CaTiO₃, CaZrO₃, CaRuO₃, and CaTi₁₋ₓAlₓO₃ can be exemplified.

As the material of the first layer of conductive complex oxide 20 among the materials listed above, LaNiO₃ may be more preferably used. The first layer of conductive complex oxide 20 may suffice if it forms at least a layer, and its film thickness may be, for example, 40-100 nm without any particular limitation.

The first layer of conductive complex oxide 20 may be formed by RF sputtering (Radio Frequency Sputtering) (hereafter also referred to as “first sputtering”). The first sputtering may be conducted where inert gas and oxygen exist together. As the inert gas, argon may be used. The flow quantity ratio between argon and oxygen is not particularly limited, and the flow ratio of argon/oxygen may be, for example, 49/1-40/10. Also, the temperature of the base substrate 1 may be 200-500° C. The power for the sputtering may be selected depending on the type of the sputter apparatus and other conditions, and may be set to, for example, 1000-1500 W.

In the first sputtering, besides inert gas and oxygen, an atmosphere containing other gas such as reactive gas may be used depending on the requirements.

(3) As shown in FIG. 3, a second layer of perovskite type conductive complex oxide 22 expressed by a general formula of ABO₃ is formed on the first layer of conductive complex oxide 20. As the material of the second layer of conductive complex oxide 22, the same materials exemplified as the materials for the first layer of conductive complex oxide 20 may be listed. The second layer of conductive complex oxide 22 can be composed of the same compound as that of the first layer of conductive complex oxide 20. As the material of the second layer of conductive complex oxide 22, LaNiO₃ may more preferably be used. The film thickness of the second layer of conductive complex oxide 22 can be selected depending on the film thickness of a layer of conductive complex oxide 2 that is to be finally obtained without any particular limitation.

The second layer of conductive complex oxide 22 may be formed by RF sputtering (hereafter also referred to as “second sputtering”), like the first layer of conductive complex oxide 20. In this step, the RF sputtering may be conducted in an atmosphere where inert gas and oxygen at least having a lower concentration than that of the first sputtering exist together. Also, in this step, the gas that is used for the RF sputtering may be composed of inert gas alone without any oxygen contained. Also, in the second sputtering, besides inert gas and oxygen, an atmosphere containing other gas such as reactive gas may be used depending on the requirements.

As the inert gas, argon may be used. The flow quantity ratio between argon and oxygen is not particularly limited if the conditions described above are satisfied, and the flow ratio of argon/oxygen may be, for example, 50/0-45/5. Also, the temperature of the base substrate 1may be 200-500° C. The power for the sputtering may be selected depending on the type of the sputter apparatus and other conditions, and may be set to, for example, 1000-1500 W.

(4) Next, to improve the crystallinity of the first and second layers of conductive complex oxide 20 and 22, a heat treatment is conducted. The heat treatment may be conducted differently depending on the material of the layer of conductive complex oxide and the like, and may be conducted at, for example, 500-800° C. The heat treatment may be conducted in an atmosphere containing at least one of argon and oxygen.

In this manner, when the layer of conductive complex oxide 2 is formed by RF sputtering, a first sputtering step which is conducted in an inert gas atmosphere such as an argon atmosphere with higher oxygen concentration, and a second sputtering step which is conducted in an inert gas atmosphere with a lower oxygen concentration than the first sputtering or without including oxygen are conducted. As a result, the layer of conductive complex oxide with excellent crystallinity and surface morphology can be formed, as it becomes clear from embodiment examples to be described below.

The layer of conductive complex oxide 2 having the first and second layers of conductive complex oxide 20 and 22 formed by the steps described above can be used as a conductive layer, an electrode or the like. For example, when a capacitor is to be obtained, the following steps (5) through (8) can be conducted.

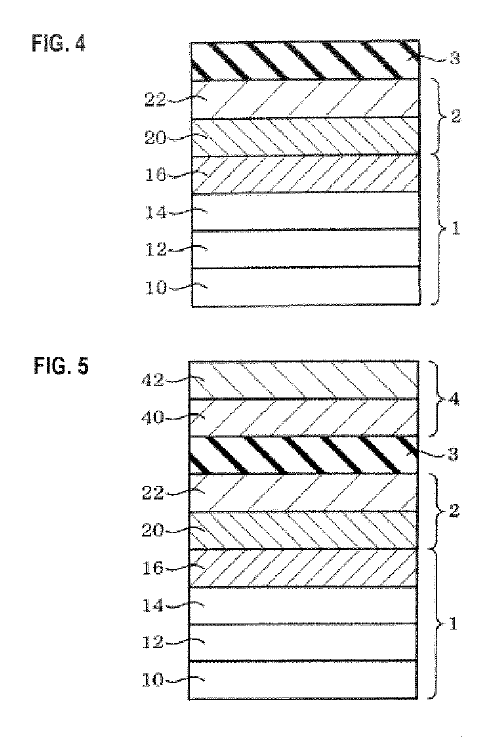

(5) As shown in FIG. 4, a ferroelectric layer 3 is formed on the second layer of conductive complex oxide 22. The type of the ferroelectric layer 3 may appropriately selected according to a device to be fabricated without any particular limitation. As the ferroelectric material of the ferroelectric layer 3, perovskite type ferroelectrics, such as, for example, PZT (Pb (Zr, Ti) O₃), PZTN (Pb (Zr, Ti, Nb) O₃), SBT (SrBi₂ Ta₂ O₉), BST ((Ba, Sr) TiO₃), and KN (KNbO₃) may be exemplified.

The ferroelectric layer 3 may be formed by using any one of the known film forming methods without any particular limitation, such as, for example, a liquid method such as a sol-gel method, or a vapor phase method such as a CVD method, a MOCVD method or a sputter method.

(6) As shown in FIG. 5, a layer of conductive complex oxide 4 is formed on the ferroelectric layer 3. In the illustrated example, the layer of conductive complex oxide 4 includes a third layer of conductive complex oxide 40 and a fourth layer of conductive complex oxide 42. The third layer of conductive complex oxide 40 may be formed by a method similar to the method used for forming the first layer of conductive complex oxide 20 described above. Also, the fourth layer of conductive complex oxide 42 may be formed by a method similar to the method used for forming the second layer of conductive complex oxide 22 described above.

More concretely, as shown in FIG. 5, the third layer of perovskite type conductive complex oxide 40 expressed by a general formula of ABO₃ is formed on the ferroelectric layer 3. The third layer of conductive complex oxide 40 may suffice if it forms at least a layer, and its film thickness may be, for example, 40-100 nm without any particular limitation.

The third layer of conductive complex oxide 40 may be formed by RF sputtering (hereafter referred to as “third sputtering”). Conditions of the sputtering are similar to the film forming conditions applied to the first layer of conductive complex oxide 20, and therefore description of their details is omitted.

(7) Next, as shown in FIG. 5, the fourth layer of perovskite type conductive complex oxide 42 expressed by a general formula of ABO₃ is formed on the third layer of conductive complex oxide 40. The film thickness of the fourth layer of conductive complex oxide 42 may be selected depending on the film thickness of the layer of conductive complex oxide 4 that is to be finally obtained, without any particular limitation.

The fourth layer of conductive complex oxide 42 may be formed by RF sputtering, like the second layer of conductive complex oxide 22. Conditions of the sputtering are similar to the film forming conditions applied to the second layer of conductive complex oxide 22, and therefore description of their details is omitted.

As the material of the third layer of conductive complex oxide 40 and the fourth layer of conductive complex oxide 42, materials similar to those used for the first layer of conductive complex oxide 20 may be exemplified. Also, the third layer of conductive complex oxide 40 and the fourth layer of conductive complex oxide 42 may be composed of the same material.

(8) Next, to improve the crystallinity of the third and fourth layers of conductive complex oxide 40 and 42, a heat treatment is conducted. The heat treatment may be conducted differently depending on the material of the layer of conductive complex oxide and the like, and may be conducted at, for example, 500-800° C. The heat treatment may be conducted in an atmosphere containing at least one of argon and oxygen.

The layer of conductive complex oxide 4 having the third and fourth layers of conductive complex oxide 40 and 42 formed by the steps described above has characteristics similar to those of the first and second layers of conductive complex oxide 20 and 22, and can be used as a conductive layer or an electrode. Also, the layer of conductive complex oxide 4 as an upper electrode and the layer of conductive complex oxide 2 as a lower layer may be provided with generally the same structure, whereby the band gaps at interfaces between the upper and lower electrodes and the ferroelectric layer can be matched, such that superior capacitor characteristics, hysteresis characteristics and piezoelectric characteristics can be obtained.

The layer of conductive complex oxide 4 is not limited to a laminated body of the third and fourth layers of conductive complex oxide 40 and 42, and may be composed of a single layer of conductive complex oxide. Also, the layer of conductive complex oxide 4 may be composed of a material different from the material composing the layer of conductive complex oxide 2.

Through the steps described above, a capacitor composed of the layer of conductive complex oxide 2 as a lower electrode, the ferroelectric layer 3, and the layer of conductive complex oxide 4 as an upper electrode can be formed on the base substrate 1.

According to the present embodiment, the following characteristics can be obtained. p At least when the layer of conductive complex oxide 2 is formed by RF sputtering, a first sputtering step that is conduced in an inert gas atmosphere such as an argon atmosphere with a higher oxygen concentration, and a second sputtering step that is conducted in an argon atmosphere with an oxygen concentration lower than the first sputtering or in an argon atmosphere that does not contain oxygen are conducted, whereby the layer of conductive complex oxide with excellent crystallinity and surface morphology can be formed, as it becomes clear from embodiment examples to be described below.

Also, capacitors having the layer of conductive complex oxide 2 have excellent hysteresis characteristics and piezoelectric characteristics, and can be used for a variety of applications, such as, semiconductor memory devices, piezoelectric elements and the like, as described below.

2. Method For Manufacturing Second Laminated Body Having Ferroelectric Layer

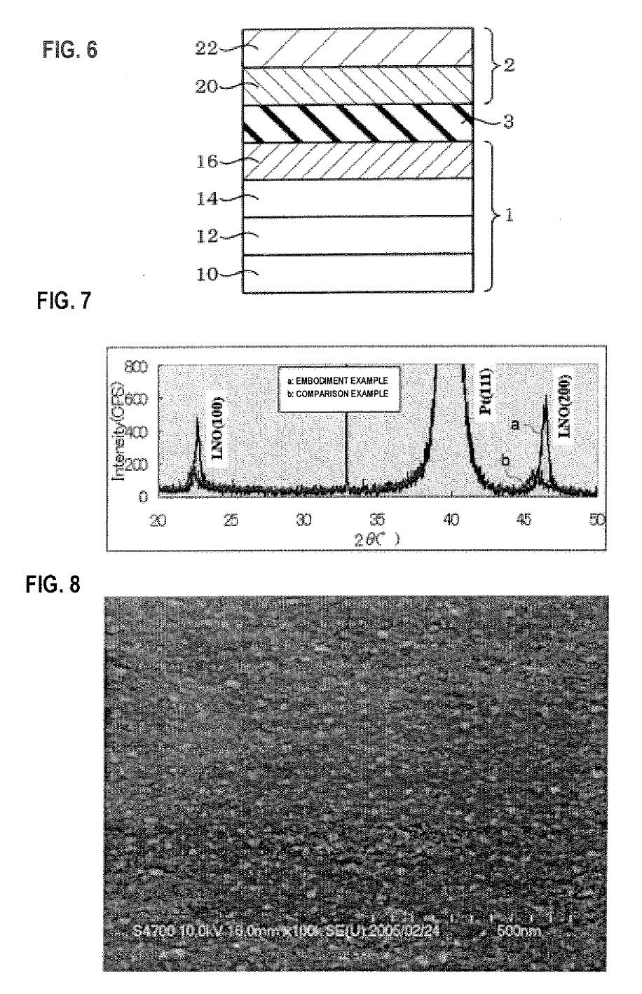

A method for manufacturing a second laminated body in accordance with an embodiment of the invention is described with reference to FIG. 6. FIG. 6 is a cross-sectional view schematically showing a step of the method for manufacturing the second laminated body. The present embodiment is different from the first laminated body in that a ferroelectric layer 3 and a layer of conductive complex oxide 1 are successively formed on a base substrate 1.

(1) As shown in FIG. 6, a base substrate 1 is prepared. The base substrate 1, in the illustrated embodiment, is formed with a silicon oxide layer 12, a titanium oxide layer 14 and a platinum layer 16 successively deposited on a silicon substrate 10. The base substrate 1 has a structure similar to that of the first laminated body, and therefore its detailed description is omitted. Also, the type of the base substrate 1 can be selected according to the usage of the layer of conductive complex oxide and the ferroelectric layer. The structure of the base substrate 1 is not particularly limited, and may be formed from an insulating substrate, a semiconductor substrate or the like. As the insulating substrate, for example, a sapphire substrate, a single crystal substrate (LiTaO₃, LiNbO₃, Li₂B₄O₇), a plastic substrate, a glass substrate or the like can be used. As the semiconductor substrate, a silicon substrate or the like can be used. Also, the base substrate 1 may be a single substrate, or a laminated body having a substrate and another layer laminated thereon.

(2) As shown in FIG. 6, a ferroelectric layer 3 is formed on the base substrate 1. The type of ferroelectric layer 3 may be appropriately selected, without any particular limitation, depending on a device to be fabricated. As the ferroelectric material of the ferroelectric layer 3, perovskite type ferroelectries, such as, for example, PZT (Pb(Zr, Ti)O₃), PZTN (Pb(Zr, Ti, Nb) O₃), SBT, BST, and KN (KNbO₃) can be exemplified.

The ferroelectric layer 3 may be formed by a known film forming method, without any particular limitation, such as, for example, a liquid phase method such as a sol-gel method, or a vapor phase method such as a CVD method, a sputter method or the like.

(3) As shown in FIG. 6, a first layer of perovskite type conductive complex oxide 20 expressed by a general formula of ABO₃ is formed on the ferroelectric layer 3. As the material of the first layer of conductive complex oxide 20, the same materials exemplified as the materials for the first layer of conductive complex oxide 20 shown in FIG. 2 through FIG. 5 may be listed. The first layer of conductive complex oxide 20 may form at least a layer, and its film thickness may be, for example, 40-100 nm without any particular limitation.

The first layer of conductive complex oxide 20 may be formed by RF sputtering (hereafter also referred to as “first sputtering”). The first sputtering may be conducted where inert gas and oxygen exist together. As the inert gas, argon may be used. The ratio between argon and oxygen is not particularly limited, and may be, for example, 49/1-40/10. Also, the temperature of the base substrate 1 may be 200-500° C. The power for the sputtering may be selected depending on the type of the sputter apparatus and other conditions, and may be set to, for example, 1000-1400 W.

(4) As shown in FIG. 6, a second layer of perovskite type conductive complex oxide 22 expressed by a general formula of ABO₃ is formed on the first layer of conductive complex oxide 20. As the material of the second layer of conductive complex oxide 22, the same materials exemplified as the materials for the second layer of conductive complex oxide 22 shown in FIG. 3 through FIG. 5 may be used. The film thickness of the second layer of conductive complex oxide 22 can be selected depending on the film thickness of a layer of conductive complex oxide 2 that is to be finally obtained, without any particular limitation.

The second layer of conductive complex oxide 22 may be formed by RF sputtering (hereafter also referred to as “second sputtering”), like the first layer of conductive complex oxide 20. In this step, the RF sputtering may be conducted in an atmosphere where inert gas and oxygen having at least a lower concentration than the first sputtering exist together. Also, in this step, the gas that is used for the RF sputtering may be composed of inert gas alone without any oxygen contained. Also, in this step, the gas that is used for the RF sputtering may be inert gas alone, without oxygen contained.

As the inert gas, argon may be used. The flow quantity ratio between argon and oxygen is not particularly limited if the conditions described above are satisfied, and the flow ratio of argon/oxygen may be, for example, 50/0-40/10. Also, the temperature of the base substrate 1 may be 200-500° C. The power for the sputtering may be selected depending on the type of the sputter apparatus and other conditions, and may be set to, for example, 1000-1400 W.

(5) Next, to improve the crystallinity of the first and second layers of conductive complex oxide 20 and 22, a heat treatment is conducted. The heat treatment may be conducted differently depending on the material of the layer of conductive complex oxide and the like, and may be conducted at, for example, 500-800° C. The heat treatment may be conducted in an atmosphere containing at least one of argon and oxygen.

The layer of conductive complex oxide 2 having the first and second layers of conductive complex oxide 20 and 22 formed in the steps described above can be used as a conductive layer, an electrode or the like.

By the steps described above, a laminated body having the ferroelectric layer 3 and the layer of conductive complex oxide 2 successively laminated on the base substrate 1 can be obtained.

According to the present embodiment, when the layer of conductive complex oxide 2 is formed by RF sputtering, a first sputtering step that is conducted in an inert gas atmosphere such as an argon atmosphere with a higher oxygen concentration and a second sputtering step that is conducted in an argon atmosphere with an oxygen concentration lower than the first sputtering or in an argon atmosphere that does not contain oxygen are conducted, whereby the layer of conductive complex oxide with excellent crystallinity and surface morphology can be formed, as it becomes clear from embodiment examples to be described below. Also, laminated bodies having the layer of conductive complex oxide 2 and the ferroelectric layer 3 can be used in a variety of applications that use surface acoustic waves, such as, surface acoustic wave elements, oscillators and the like, as described below.

3. EMBODIMENT EXAMPLES

Embodiment examples of the invention are described below, but the invention is not limited to the embodiments.

(a) As a sample of the embodiment example, a laminated body shown in FIG. 3 was formed. More specifically, a first layer of LaNiO₃ as the first layer of conductive complex oxide 20 and a second layer of LaNiO₃ as the second layer of conductive complex oxide 22 were formed on a base substrate 1.

As the base substrate 1, a base substrate in which a silicon oxide layer 12, a titanium oxide layer 14 and a platinum layer 14 are formed by the method described above on a silicon substrate 10 was used. As the first LaNiO₃ layer, a LaNiO₃ layer having a film thickness of 40 nm, which was formed by an RF sputter method under conditions with the power being 1500 W, the gas flow quantity ratio of argon/oxygen being 40/10, and the substrate temperature being 400° C., was used. As the sputter target, a LaNiO₃ (composition: stoichiometry) was used. As the second LaNiO₃ layer, a LaNiO₃ layer having a film thickness of 40 nm, which was formed by an RF sputter method under conditions with the power being 1500 W, the gas flow quantity ratio of argon/oxygen being 50/0, and the substrate temperature being 400° C., was used. As the sputter target, a LaNiO₃ (composition: stoichiometry) was used.

Also, a comparison sample having a base substrate 1 and a third LaNiO₃ layer formed thereon was used. As the third LaNiO₃ layer, a LaNiO₃ layer having a film thickness of 80 nm, which was formed under the same conditions as the film forming conditions applied for forming the first LaNiO₃ layer (with the power being 1500 W, the gas flow quantity ratio of argon/oxygen being 40/10, and the substrate temperature being 400° C.), was used.

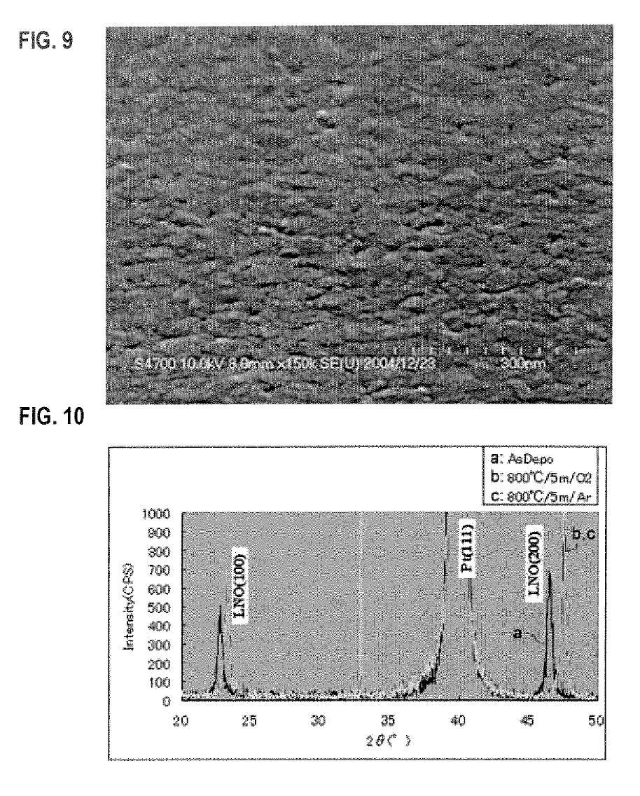

Surfaces of the sample and the comparison sample obtained in the manner described above were observed by X-ray diffraction (2θ-measurement) and an electron microscope. The results are shown in FIG. 7 through FIG. 9. FIG. 7 shows the results of X-ray diffraction. In FIG. 7, the result of the sample of the embodiment example is indicated by the sign a, and the result of the sample of the comparison example is indicated by the sign b. FIG. 8 shows the morphology of the sample of the embodiment example, and FIG. 9 shows the morphology of the sample of the comparison example.

It was confirmed from the results obtained that, according to the sample of the embodiment example, the LaNiO₃ layer with outstanding (100) orientation and excellent surface morphology was obtained. Also, it was confirmed that, according to the sample of the comparison example, the LaNiO₃ layer with substantially weaker (100) orientation than the embodiment example and poorer surface morphology than the embodiment example was obtained.

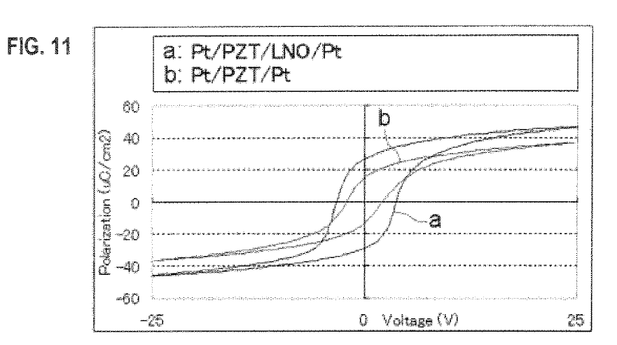

(b) Next, the samples of the embodiment example were heat-treated in an argon atmosphere or an oxygen atmosphere to form samples, and X-ray diffraction measurement was conducted on the samples. The heat treatment was conducted at 800° C. for five minutes. The results are shown in FIG. 10. In FIG. 10, the sign a indicates the result of the sample of the embodiment example before heat treatment, the sign b indicates the result of the sample that was heat-treated in an oxygen atmosphere, and the sign c indicates the result of the sample that was heat-treated in an argon atmosphere. It is confirmed from FIG. 10 that the (100) orientation became more pronounced by the heat treatment. Also, generally similar results were obtained with both of the samples heat-treated in an oxygen atmosphere and an argon atmosphere.

(c) A capacitor was formed using the sample that had been heat-treated and obtained in the embodiment example (b) described above. More concretely, a PZT layer as a ferroelectric layer was formed on the LaNiO₃ layer, and a platinum layer was further formed on the PZT layer. The PZT layer was formed by a sol-gel method. The sample is referred to as a “capacitor sample.” Also, as a sample for comparison, a capacitor sample for comparison was obtained in a similar manner as the sample of the embodiment example except that a LaNiO₃ layer was not formed. Hysteresis characteristics of the capacitor samples were obtained. The results are shown in FIG. 11. In FIG. 11, the sign a indicates the hysteresis characteristic of the capacitor sample of the embodiment example, and the sign b indicates the hysteresis characteristic of the capacitor sample of the comparison example.

It is confirmed from FIG. 11 that the sample of the embodiment example has better hysteresis characteristic than that of the sample of the comparison example.

4. Devices

Devices in accordance with an embodiment of the invention include parts having a laminated body obtained by the method for manufacturing a laminated body having a ferroelectric layer in accordance with the embodiment of the invention, and electronic devices having the aforementioned parts. Examples of the devices to which the method for manufacturing a device in accordance with the embodiment of the invention is applicable are described below.

4.1. Semiconductor Element

Next, a semiconductor element including a laminated body obtained by the manufacturing method in accordance with an embodiment of the invention is described. In the present embodiment, a ferroelectric memory device including a ferroelectric capacitor, which is an example of a semiconductor element, is described as an example.

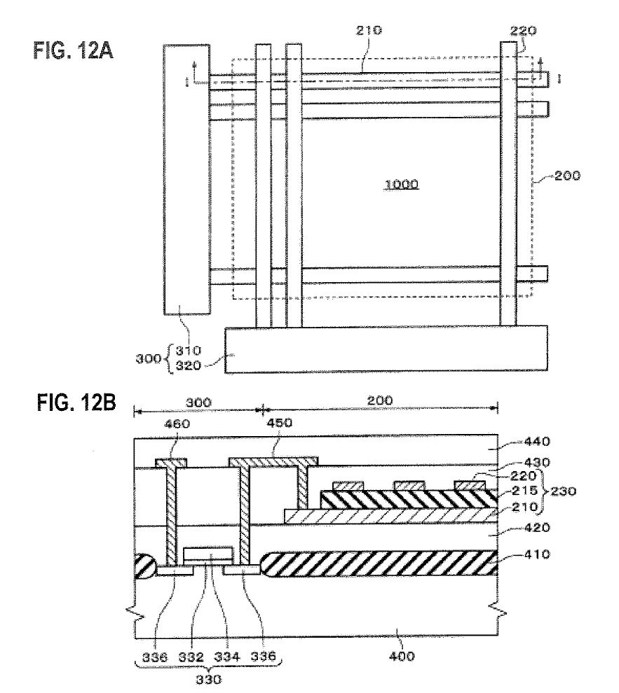

FIG. 12A and FIG. 12B are views schematically showing a ferroelectric memory device 1000 having a laminated body obtained by the manufacturing method in accordance with the present embodiment described above. It is noted that FIG. 12A shows a plane configuration of the ferroelectric memory device 1000, and FIG. 12B is a cross-sectional view taken along a line I-I in FIG. 12A.

The ferroelectric memory device 1000 has a memory cell array 200 and a peripheral circuit section 300, as shown in FIG. 12A. The memory cell array 200 includes lower electrodes (word lines) 210 for selection of rows, and upper electrodes (bit lines) 220 for selection of columns, which are disposed orthogonal to one another. Also, the lower electrodes 210 and the upper electrodes 220 are arranged in stripes composed of a plurality of line shaped signal electrodes. It is noted that the signal electrodes can be for ed such that the lower electrodes 210 may define bit lines, and the upper electrodes 220 may define word lines. The peripheral circuit section 300 includes various circuits that selectively write or read information in or from the above-described memory cell array 200 and, for example, is formed from a first driving circuit 310 to control the lower electrodes 210 selectively, a second driving circuit 320 to control the upper electrodes 220 selectively, and a signal detection circuit such as a sense amplifier (omitted in the figure) and the like.

As shown in FIG. 12B, a ferroelectric layer 215 is disposed between the lower electrodes 210 and the upper electrodes 220. In the memory cell array 200, memory cells that function as ferroelectric capacitors 230 are formed in areas where the lower electrodes 210 and the upper electrodes 220 intersect one another.

The ferroelectric capacitor 230 can be formed by the method for forming a laminated body in accordance with an embodiment of the invention. In other words, at least the lower electrode 210 and the ferroelectric layer 215 can be formed by a manufacturing method in accordance with an embodiment of the invention, for example, the method for manufacturing a first laminated body. The lower electrode 210 may be composed of a layer of conductive complex oxide 2 (having a first layer of conductive complex oxide 20 and a second layer of conductive complex oxide 22) shown in FIG. 2 through FIG. 5, and the ferroelectric layer 215 is composed of a ferroelectric layer 3 shown in FIG. 5. Also, the upper electrode 22 may be composed of a layer of conductive complex oxide 4 shown in FIG. 5. Furthermore, a first interlayer dielectric layer 420 corresponds to the base substrate 1 shown in FIG. 5. The interlayer dielectric layer 420 may have a barrier layer (not shown) at its topmost layer.

The ferroelectric layer 215 may only have to be disposed between areas where at least the lower electrodes 210 and the upper electrodes 220 are intersecting one another.

Also, the peripheral circuit section 300 includes MOS transistors 330 formed on the semiconductor substrate 400, as shown in FIG. 12B. The MOS transistor 330 has a gate insulation film 332, a gate electrode 334, and source/drain regions 336. The MOS transistors 330 are isolated from one another by an element isolation area 410. A first interlayer dielectric film 420 is formed on the semiconductor substrate 400 on which the MOS transistor 330 is formed. Further, the peripheral circuit section 300 and the memory cell array 200 are electrically connected to one another by wiring layers 450. Furthermore, the ferroelectric memory device 1000 is provided with a second interlayer dielectric film 430 and an insulating protective layer 440.

FIG, 13 shows a structural drawing of a 1T1C type ferroelectric memory device 500 as another example of a semiconductor device. FIG. 14 is an equivalent circuit diagram of the ferroelectric memory device 500.

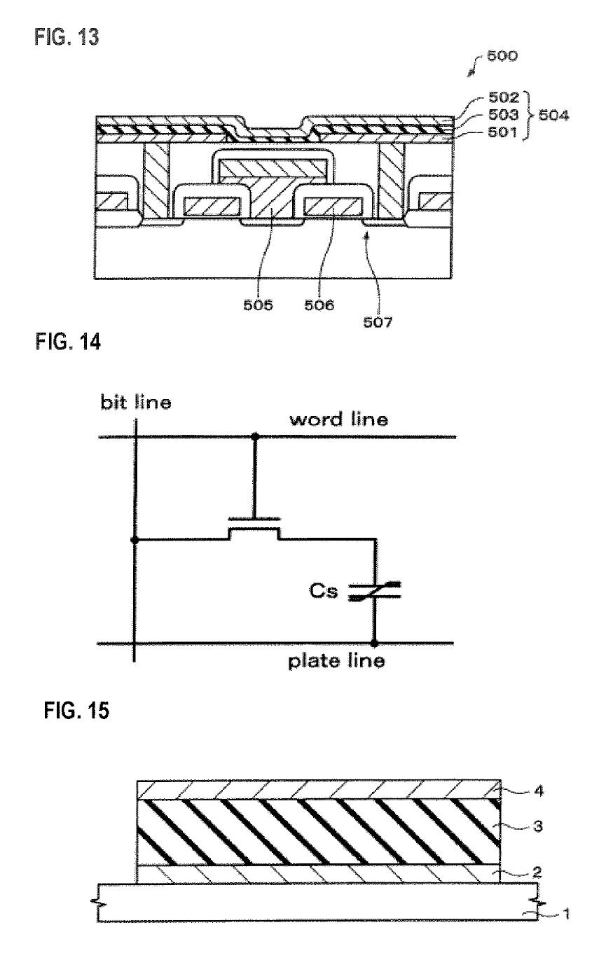

As shown in FIG. 13, the ferroelectric memory device 500 is a memory element having a structure similar to that of a DRAM, which is formed from a capacitor 504 (1C) composed of a lower electrode 501, an upper electrode 502 that is connected to a plate line and a ferroelectric layer 503, and a switching transistor element 507 (1T), having source/drain electrodes, one of them being connected to a data line 505, and a gate electrode 506 that is connected to a word line. The 1T1C type memory can perform writing and reading at high-speeds at 100 ns or less, and because written data is nonvolatile, it is promising as the replacement of SRAM.

At least the lower electrode 501 and the ferroelectric layer 503, and further the upper electrode 502 if necessary, of the ferroelectric memory device 500 may be formed by the method for manufacturing a first laminated body in accordance with the embodiment of the invention. The lower electrode 501 is composed of the layer of conductive complex oxide 2 (having the first layer of conductive complex oxide 20 and the second layer of conductive complex oxide 22) shown in FIG. 2 through FIG. 5, and the ferroelectric layer 503 may be composed of the ferroelectric layer 3 shown in FIG. 5. Also, the upper electrode 502 may be composed of the layer of conductive complex oxide 4 shown in FIG. 5.

The semiconductor device in accordance with the present embodiment can also be applied to 2T2C type ferroelectric memory devices and the like without being limited to the above.

4.2. Piezoelectric Element

Next, an example in which the method for manufacturing a laminated body in accordance with the embodiment of the invention is applied to a method for manufacturing a piezoelectric element is described.

FIG. 15 is a cross-sectional view of a piezoelectric element having a laminated body (a first laminated body) formed by the manufacturing method in accordance with the embodiment of the invention. The piezoelectric element includes a base substrate 1, a lower electrode 2 formed on the base substrate 1, a piezoelectric layer 3 formed on the lower electrode 2, and an upper electrode 4 formed on the piezoelectric layer 3. FIG. 15 corresponds to FIG. 5.

In other words, at least the lower electrode 2 and the piezoelectric layer (a ferroelectric layer) 3, and further the upper electrode 4 if necessary, of the piezoelectric element shown in FIG. 15 can be formed by the method for manufacturing a first laminated body in accordance with the embodiment of the invention. The lower electrode 2 is composed of the layer of conductive complex oxide 2 (including the first layer of conductive complex oxide 20 and the second layer of conductive complex oxide 22) shown in FIG. 2 through FIG. 55 and the piezoelectric layer 3 is composed of the ferroelectric layer 3 shown in FIG. 5. Also, the upper electrode 4 may be composed of the layer of conductive complex oxide 4 shown in FIG. 5.

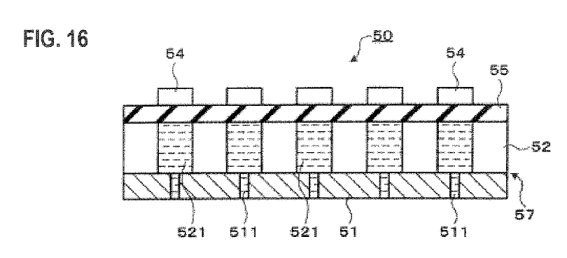

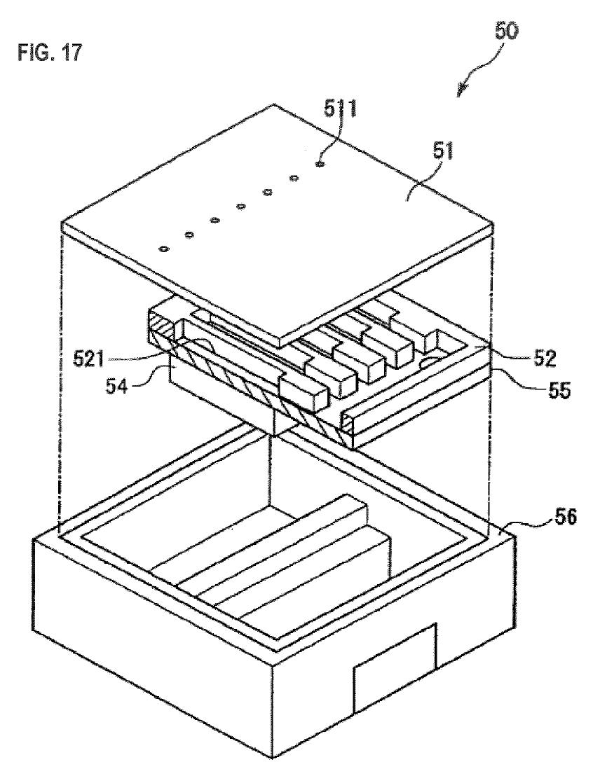

The base substrate 1 may be composed of a single-crystal silicon substrate with a (110) orientation and a thermal oxidation film formed on the surface of the single-crystal silicon substrate. By processing the base substrate 1, the base substrate 1 can have ink cavities 521 in an ink jet recording head 50 as described below (see FIG. 16).

4.3. Inkjet Recording Head

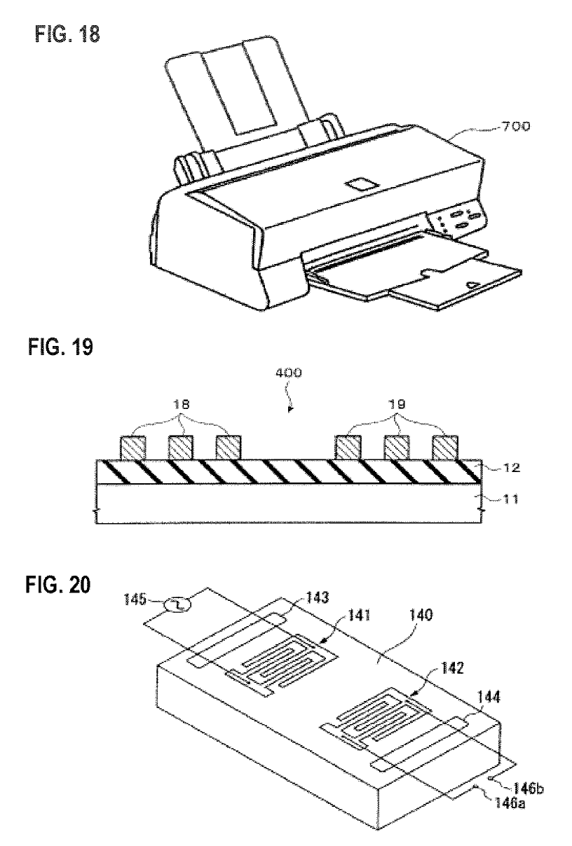

Next, an inkjet recording head in which the above-described piezoelectric element functions as a piezoelectric actuator, and an inkjet printer having the inkjet recording head are described. FIG. 16 is a side cross-sectional view schematically showing a structure of the inkjet recording head in accordance with the present embodiment, and FIG. 17 is an exploded perspective view of the inkjet recording head, which is shown upside down with respect to a state in normal use. FIG. 18 shows an ink jet printer 700 that has the inkjet recording head in accordance with the present embodiment.

As shown in FIG. 16 and FIG. 17, the inkjet recording head 50 includes a head main body (base substrate) 57 and piezoelectric sections 54 formed on the head main body 57. The piezoelectric section 54 is provided with a piezoelectric element shown in FIG. 15, and the piezoelectric element is composed of a lower electrode 2, a piezoelectric layer (ferroelectric layer) 3 and an upper electrode 4 successively laminated. The piezoelectric section 54 functions as a piezoelectric actuator in the inkjet recording head.

The head main body (base substrate) 57 is formed from a nozzle plate 51, an ink chamber substrate 52, and an elastic film 55, which are housed in a housing 56, thereby forming the ink jet recording head 50.

Each of the piezoelectric sections is electrically connected to a piezoelectric element driving circuit (not shown), and is structured to operate (vibrate, deform) based on signals of the piezoelectric element driving circuit. In other words, each of the piezoelectric sections 54 functions as a vibration source (head actuator). The elastic film 55 vibrates (deforms) by vibrations (deformation) of the piezoelectric section 54, and functions to instantaneously increase the inner pressure of the cavity 521.

Although an ink jet recording head that discharges ink is described above as one example, the present embodiment is intended to be generally applicable to all liquid jet heads and liquid jet devices that use piezoelectric elements. As the liquid jet head, for example, a recording head used for an image recording device such as a printer, a color material jet head used to manufacture color filters of liquid crystal displays, and the like, an electrode raw material jet head used for forming electrodes of organic EL displays, FED (plane emission display), and the like, a bio-organic material jet head used for manufacturing biochips, and the like can be enumerated.

4.4. Surface Acoustic Wave Element

Next, an example of a surface acoustic wave element to which the method for manufacturing a laminated body (the method for manufacturing a second laminated body) in accordance with the embodiment of the invention is applied is described with reference to the accompanying drawings.

FIG. 19 is a cross-sectional view schematically showing a surface acoustic wave element 400 in accordance with the present embodiment.

The surface acoustic wave element 400 includes a substrate 11, a piezoelectric layer 12 formed on the substrate 11, and inter digital type electrodes (hereafter referred to as inter digital transducers or “IDT electrodes”) 18 and 19 formed on the piezoelectric layer 12. The IDT electrodes 18 and 19 have predetermined patterns.

The surface acoustic wave element 400 in accordance with the present embodiment may be formed by using the method for manufacturing a laminated body (the method for manufacturing a second laminated body) in accordance with the embodiment of the invention, for example, as follows.

First, a piezoelectric layer 12 (corresponding to the ferroelectric layer 3 shown in FIG. 6) is formed on a substrate 11 shown in FIG. 16 (corresponding to the base substrate 1 shown in FIG. 6). Then, first and second layers of conductive complex oxide 20 and 22 shown in FIG. 6 are formed to thereby form a conductive layer (corresponding to the layer of conductive complex oxide 2). Then, by using known lithography technique and etching technique, the conductive layer (the layer of conductive complex oxide 2) is patterned to thereby form IDT electrodes 18 and 19 on the piezoelectric layer 12.

4.5. Frequency Filter

Next, an example of a frequency filter to which the method for manufacturing a laminated body (the method for manufacturing a second laminated body) in accordance with the embodiment of the invention is applied is described with reference to the accompanying drawings. FIG. 20 is a view schematically showing the frequency filter in accordance with the present embodiment.

As shown in FIG. 20, the frequency filter has a base substrate (laminated body) 140. As the laminated body 140, a laminated body similar to the one used in the surface acoustic wave element 400 described above may be used (see FIG. 19). More specifically, the laminated body 140 includes a base substrate 11 and a piezoelectric layer 12 formed on the base substrate 11, as shown in FIG. 19.

On an upper surface of the base substrate 140, IDT electrodes 141 and 142 are formed. Acoustic absorber sections 143 and 144 are formed on the upper surface of the base substrate 140 in a manner to interpose the IDT electrodes 141 and 142. The acoustic absorber sections 143 and 144 absorb surface acoustic waves propagating on the surface of the base substrate 140. A high frequency signal source 145 is connected with the IDT electrode 141, and a signal line is connected with the IDT electrode 142. The laminated body 140 and the IDT electrodes 141 and 142 may be formed in a manner similar to the surface acoustic wave element 400 described above.

4.6. Oscillator

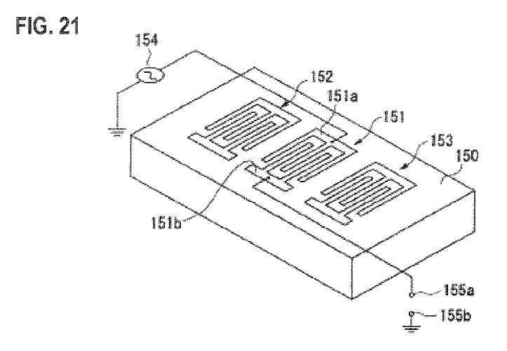

Next, an example of an oscillator to which the method for manufacturing a laminated body (the method for manufacturing a second laminated body) in accordance with the embodiment of the invention is applied is described with reference to the accompanying drawings. FIG. 21 is a view schematically showing an oscillator in accordance with the present embodiment.

As shown in FIG. 21, the oscillator has a laminated body 150. As the laminated body 150, a laminated body similar to the one used in the surface acoustic wave element 400 described above (see FIG. 9) may be used. In other words, the laminated body 150 has, as shown in FIG. 19, a base substrate 11 and a piezoelectric layer 12 formed on the base substrate 11.

On an upper surface of the base substrate 150, an IDT electrode 151 is formed. Furthermore, IDT electrodes 152 and 153 are formed in a manner to interpose the IDT electrode 151. A high frequency signal source 154 is connected with one of comb teeth-shape electrodes 151a composing the IDT electrode 151, and a signal line is connected with the other comb teeth-shape electrode 151b. It is noted that the IDT electrode 151 corresponds to an electric signal application electrode, while the IDT electrodes 152 and 153 correspond to resonating electrodes for resonating a specific frequency or a specific band frequency of the surface acoustic waves generated by the IDT electrode 151. It is noted here that the laminated body 150 and the IDT electrodes 152 and 153 may be formed in a manner similar to the surface acoustic wave element 400 described above.

Also, the oscillator described above may be applied to a VCSO (Voltage Controlled SAW Oscillator).

The present invention is not limited to the embodiments described above, and many modifications can be made. For example, the present invention may include compositions that are substantially the same as the compositions described in the embodiments (for example, a composition with the same function, method and result, or a composition with the same objects and result). Also, the present invention includes compositions in which portions not essential in the compositions described in the embodiments are replaced with others. Also, the present invention includes compositions that achieve the same functions and effects or achieve the same objects of those of the compositions described in the embodiments. Furthermore, the present invention includes compositions that include publicly known technology added to the compositions described in the embodiments.

What is claimed is:

1. A method for manufacturing a conductive complex oxide layer, the method comprising the steps of:
forming, above a base substrate, a first layer of conductive complex oxide expressed by a general formula of ABO₃ by first sputtering with first oxygen concentration; and
forming, above the first layer of conductive complex oxide, a second layer of conductive complex oxide expressed by a general formula of ABO₃ by second sputtering at least with second oxygen concentration lower than the first oxygen concentration.

2. A method for manufacturing a conductive complex oxide layer according to claim 1, wherein the first sputtering is conducted where inert gas and oxygen coexist.

3. A method for manufacturing a conductive complex oxide layer according to claim 1, wherein the first layer of conductive complex oxide and the second layer of conductive complex oxide are composed of an identical compound.

4. A method for manufacturing a conductive complex oxide layer according to claim 1, wherein the second sputtering is conducted in an atmosphere that does not include oxygen.

5. A method for manufacturing a conductive complex oxide layer according to claim 1, further comprising heat-treating after the second layer of conductive complex oxide is formed.

6. A method for manufacturing a conductive complex oxide layer according to claim 1, wherein an element A in the general formula of ABO₃ is at least one element selected from the group consisting of La, Ca, Sr, Mn, Ba and Re, and an element B in the general formula of ABO₃ is at least one element selected from the group consisting of Ti, V, Sr, Cr, Fe, Co, Ni, Cu, Ru, Ir, Pb and Nd.

7. A method for manufacturing a conductive complex oxide layer according to claim 1, wherein an element A in the general formula of ABO₃ is La, and an element B is Ni.

8. A method for manufacturing a conductive complex oxide layer according to claim 1, wherein the sputtering is RF sputtering.

9. A method for manufacturing a laminated body including a ferroelectric layer, the method comprising the steps of:
forming, above a base substrate, a first layer of conductive complex oxide expressed by a general formula of ABO₃ by first sputtering with first oxygen concentration;
forming, above the first layer of conductive complex oxide, a second layer of conductive complex oxide expressed by a general formula of ABO₃ by second sputtering at least with second oxygen concentration lower than the first oxygen concentration; and
forming a ferroelectric layer above the second layer of conductive complex oxide.

10. A method for manufacturing a laminated body having a ferroelectric layer according to claim 9, comprising the step of forming, above the ferroelectric layer, a layer of conductive complex oxide expressed by a general formula of ABO₃ by sputtering.

11. A method for manufacturing a laminated body having a ferroelectric layer according to claim 10, wherein the step of forming the layer of conductive complex oxide includes the step of forming a third layer of conductive complex oxide expressed by a general formula of ABO₃ by third sputtering conducted with the first oxygen concentration, and the step of forming, above the third layer of conductive complex oxide, a fourth layer of conductive complex oxide expressed by a general formula of ABO₃ by fourth sputtering conducted at least with the second oxygen concentration having a lower oxygen concentration than the first oxygen concentration.

12. A method for manufacturing a device, the method comprising the method for manufacturing a laminated body having a ferroelectric layer recited in claim 9.

13. A method for manufacturing a laminated body having a ferroelectric layer, the method comprising the steps of:
forming a ferroelectric layer above a base substrate;
forming, above the ferroelectric layer, a first layer of conductive complex oxide expressed by a general formula of ABO₃ by first sputtering with first oxygen concentration; and
forming, above the first layer of conductive complex oxide, a second layer of conductive complex oxide expressed by a general formula of ABO₃ by second sputtering at least with second oxygen concentration lower than the first oxygen concentration.

14. A method for manufacturing a device, the method comprising the method for manufacturing a device recited in claim 13.
